(19) United States
(12) Patent Application Publication
(10) Pub. No.: US 2020/0006570 A1
(43) Pub. Date: Jan. 2, 2020

(54) CONTACT STRUCTURES FOR THIN FILM TRANSISTOR DEVICES

(71) Applicant: Intel Corporation, Santa Clara, CA (US)

(72) Inventors: Van H. LE, Portland, OR (US); Rajat PAUL, Portland, OR (US); Abhishek SHARMA, Hillsboro, OR (US); Tahir GHANI, Portland, OR (US); Jack KAVALIEROS, Portland, OR (US); Gilbert DEWEY, Beaverton, OR (US); Matthew METZ, Portland, OR (US); Miriam RESHOTKO, Portland, OR (US); Benjamin CHU-KUNG, Portland, OR (US); Justin WEBER, Portland, OR (US); Shriram SHIVARAMAN, Hillsboro, OR (US)

(21) Appl. No.: 16/024,687

(22) Filed: Jun. 29, 2018

(51) Int. Cl. H01L 29/786; H01L 29/45

(52) U.S. Cl. CPC H01L 29/78618; H01L 29/45; H01L 29/7869

(57) ABSTRACT

Embodiments of the present disclosure are contact structures for thin film transistor (TFT) devices. One embodiment is a TFT device comprising: a substrate; a gate formed above the substrate; a TFT channel formed above the substrate; and a pair of contacts formed on the TFT channel, wherein each of the contacts comprises one or more layers including: a metal that is non-reactive with a material of the TFT channel; or a plurality of layers including a first metal layer formed on a second layer, the second layer in contact with the TFT channel and between the first mater layer and the TFT channel. Other embodiments may be disclosed and/or claimed.

### TECHNICAL FIELD

The present disclosure relates to the field of semiconductors. More specifically, the present disclosure is related to contact structures for thin film transistor (TFT) devices.

### BACKGROUND

A typical back-gated long-channel TFT device may utilize reactive metal contacts for the specific reason of lowering contact resistance by injecting contact doping through reaction of the metal with the semiconducting oxide. However, these same reactive metal contacts may not be compatible with small channel length devices (as they may cause unwanted doping or destabilization of the channel and hence loss of gate control). The reactive metal contacts may cause phase segregation of pure metal out of the semiconducting oxide. The pure metal may have a relatively low melting point, which may create thermal processing limitations (some subsequent processing steps, such as annealing, may be associated with a temperature greater than the melting point of the metal, and may thus melt the metal, which may damage the TFT device).

### BRIEF DESCRIPTION OF THE DRAWINGS

FIG. 1 is an illustration of a contact structure for a thin film transistors (TFT) device, according to various embodiments.

FIG. 2A is an illustration of an example single layer contact structure including contacts formed from a layer of non-reactive metal.

FIG. 2B is graph illustrating metals that are non-reactive with an indium gallium zinc oxide (IGZO) TFT device.

FIG. 3 is an illustration of an example plural layer contact structure including contacts that each include an absorption layer, according to various embodiments.

FIG. 4 is an illustration of an example contact plural layer structure including contacts that each include a barrier layer, according to various embodiments.

FIG. 5 illustrates a back-gated architecture employing contacts similar to the contacts of FIG. 1 or any other contacts described herein.

FIG. 6 illustrates a non-back-gated architecture employing contacts similar to the contacts of FIG. 1 or any other contacts described herein.

FIG. 7 is an illustration of a computing device built in accordance with an embodiment of the present disclosure.

### DETAILED DESCRIPTION

Described herein are contract structures for TFT devices. In the following description, various aspects of the illustrative implementations will be described using terms commonly employed by those skilled in the art to convey the substance of their work to others skilled in the art. However, it will be apparent to those skilled in the art that the embodiments described herein may be practiced with only some of the described aspects. For purposes of explanation, specific numbers, materials and configurations are set forth in order to provide a thorough understanding of the illustrative implementations. However, it will be apparent to one skilled in the art that the described embodiments may be practiced without the specific details. In other instances, well-known features are omitted or simplified in order not to obscure the illustrative implementations.

Various operations will be described as multiple discrete operations, in turn, in a manner that is most helpful in understanding the present disclosure; however, the order of description should not be construed to imply that these operations are necessarily order dependent. In particular, these operations need not be performed in the order of presentation.

The terms “over,” “under,” “between,” and “on” as used herein refer to a relative position of one material layer or component with respect to other layers or components. For example, one layer disposed over or under another layer may be directly in contact with the other layer or may have one or more intervening layers. Moreover, one layer disposed between two layers may be directly in contact with the two layers or may have one or more intervening layers. In contrast, a first layer “on” a second layer is in direct contact with that second layer. Similarly, unless explicitly stated otherwise, one feature disposed between two features may be in direct contact with the adjacent features or may have one or more intervening layers.

A first implementation of a contact structure for a TFT device may use stable and reaction-free metal contacts based on thermodynamic calculations to 1) eliminate adverse reactivity with metal oxide semiconductors which destabilizes channel and/or 2) to provide short channel devices with good on-state currents (e.g., low Rc). In contrast to some known metal contacts, these implementations may not react adversely with metal oxide semiconductors to destabilize it.

A second implementation of a contact structure for a TFT device may use the same or different metals than the first implementation, but may include plural layers including a metal-absorbing layer in the contact to mitigate the release of metal from the semiconducting oxide during reaction with the contact. This metal-absorbing layer may mitigate the release of free metal atoms from the contact reaction with the semiconducting oxide. The metal-absorbing layer may absorb and bind free metal atoms that would normally have a very low melting point. This absorption of free metal from the semiconducting oxide may increase the robustness of the contacts to subsequent processing, especially anneals by effectively increasing the melting point of the semiconducting oxide/metal contact region. If contact metals are used that alloy well with the liberated metal, this can mitigate the impact by absorbing the liberated metal into the contact region and reacting to it to increase the melting point.

A third implementation of a contact structure for a TFT device may use the same or different metals than the first implementation, but may include plural layers including an insulating barrier between the reactive metal contacts and the semiconducting-oxide film. This insulating barrier may mitigate metal reactions with the semiconducting-oxide film, therefore reducing dopant injection, and stopping short-channel properties from degrading due to contact reactivity. This insulating barrier may degrade contact resistance, while improving stability of the contact region. However, in order to minimize impact to contact resistance, the insulating layer may be kept thin and the conduction-band offset between the insulating layer and the semiconducting oxide may be kept small.

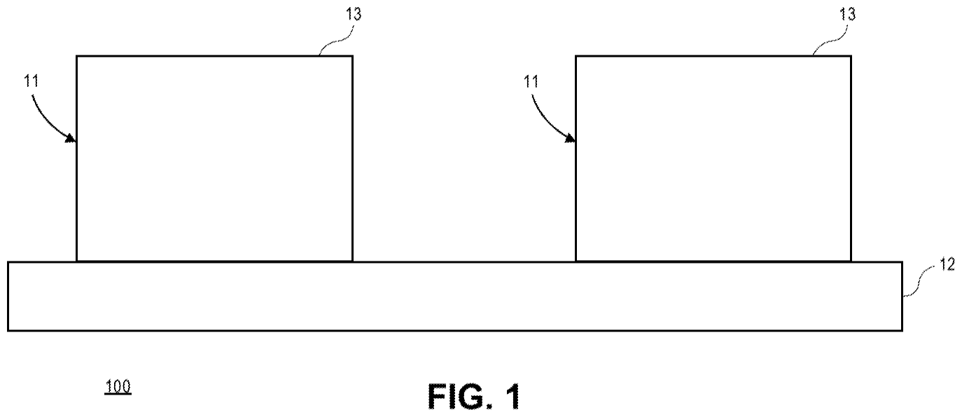

FIG. 1 is an illustration of a contact structure 100 for a thin film transistors (TFT) device, according to various embodiments. The contact structure 100 for the TFT device may include a pair of contacts 11 formed on a TFT channel 12. The TFT device may be a short channel TFT device (e.g., in which the channel length is comparable to the depletion-layer widths of the source and drain junctions), according to various embodiments. A material of the TFT channel 12 may include a metal oxide. In some examples, the material of the TFT channel 12 may include silicon germanium, zinc oxide, gallium oxide, indium oxide, indium gallium zinc oxide (IGZO), tin oxide, copper oxide, or the like, or combinations thereof.

Each contact 11 may include one or more layers 13. In some embodiments, the one or more layers 13 may include a metal that is non-reactive with a material of the TFT channel 12. In these embodiments, the contract structure 100 may be a single layer contact structure, although this is not required.

In other embodiments, the one or more layers 13 may include plural layers including a first metal layer formed on a second layer. The second layer may be in contact with the TFT channel 12 between the first metal layer and the second layer. In these embodiments, the first metal layer may be any metal such as the metals used in contacts of long channel TFT devices.

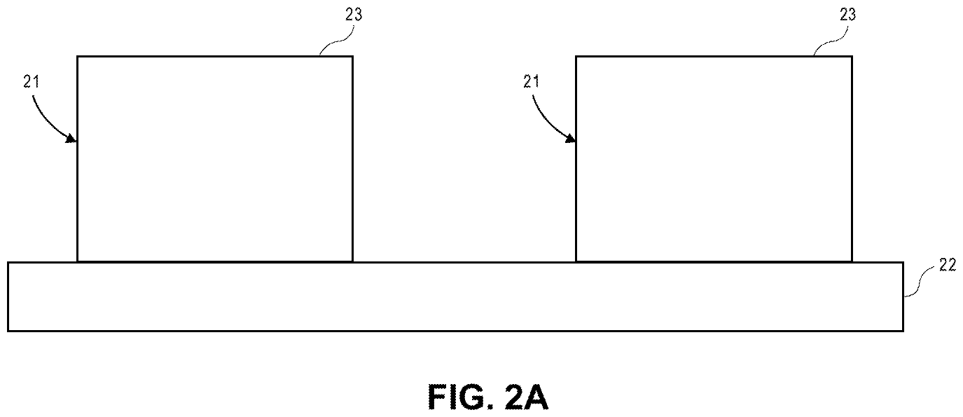

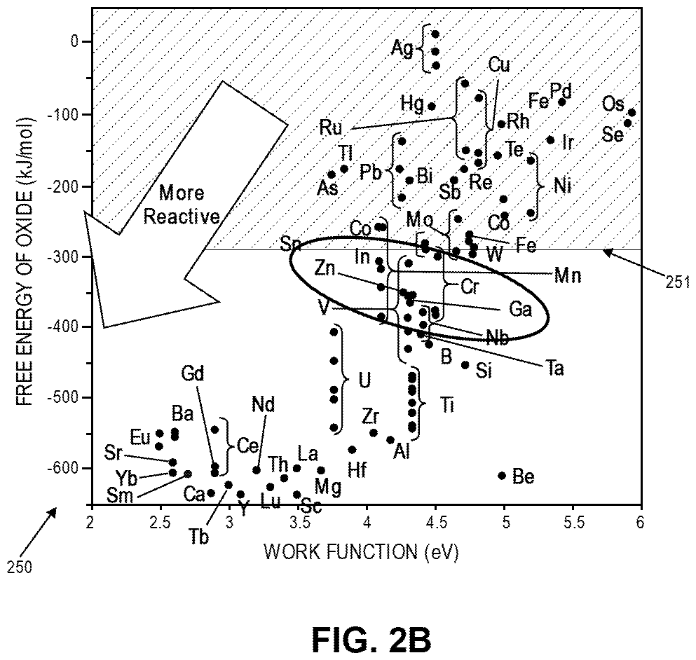

FIG. 2A is an illustration of an example single layer contact structure including contacts 21 formed from a layer 23 of non-reactive metal. Metals such as hafnium or titanium, for example, may be reactive with material of a TFT channel (these metals may remove oxygen from a metal oxide of the TFT channel making the TFT channel material oxygen deficient). In response to a state of oxygen deficiency, the TFT channel material may release free metals (e.g., disassociating the film and/or forming an oxygen interfacial layer). An electronic microscope image of a cross-section of a TFT device with a damaged TFT channel having dissociations may show a non-uniform appearance in the TFT channel.

In contrast, a non-reactive metal may not remove the oxygen from the TFT channel material (e.g., may not oxidize as readily). An electronic microscope image of a cross-section of a TFT device including the single layer contact structure similar to FIG. 2A (with the non-reactive metal) may show a substantially uniform appearance in the TFT channel.

In some examples, a Gibs free energy value (J/mol) of the metal of the layer 23 is less favorable compared to the TFT material (e.g., less negative than a Gibs free energy value of semiconducting oxide of the TFT channel 22). FIG. 2B is graph 250 illustrating metals that are non-reactive with an indium gallium zinc oxide (IGZO) TFT device. Gibs free energy values of Indium, Gallium, and Zinc are more negative than −300 KJ/mol, as illustrated in graph 250. Therefore, examples of non-reactive metals for an IGZO TFT device may include any of the metals above dividing line 251. For example, non-reactive metals for an IGZO device may include Cobalt-Iron (e.g., CoFe).

In other examples with a different TFT device (e.g., other than an IGZO TFT device, such as an IZO TFT device, a Gallium oxide TFT device, an Indium oxide TFT device, etc.), the dividing line may be a different value based on a Gibs free energy value of the materials of the TFT channel of such a TFT device.

In some embodiments, the non-reactive metal may also be selected based on work function. In particular, the non-reactive metal may have a work function that is aligned with a work function of the TFT channel material. A material above the dividing line 251, Palladium (Pd) for instance, may have a significantly different (e.g., higher) work function than an IGZO TFT device, e.g., more than a one eV difference. A palladium contact may produce a contact resistivity with the TFT channel of an IGZO TFT device that may be unacceptable for some systems. In contrast, a material above the dividing line 251 and having a work function closer to the material of the TFT channel material may be desirable for some implementations.

Although FIG. 2A illustrates a single layer contact structure employing a non-reactive metal, other embodiments may use a non-reactive metal in a plural layer contact structure. Such an embodiment may include a contact including a non-reactive metal layer and one or more other metal layers, where the non-reactive metal layer is between the TFT channel and the one or more other metal layers.

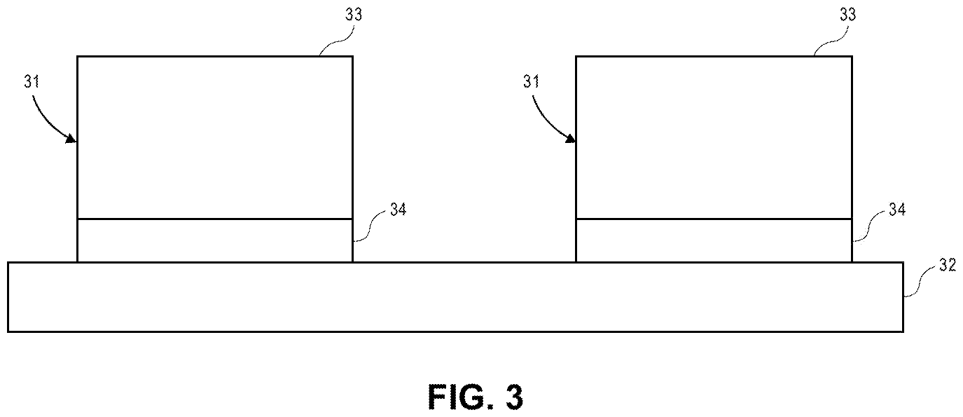

FIG. 3 is an illustration of an example plural layer contact structure including contacts 31 that each include an absorption layer 34, according to various embodiments. Due to the absorption layer 34, the metal layer 33 of the pair of contacts 31 need not be limited to the example non-reactive metals described with reference to FIGS. 2A-B (for instance, due to the absorption layer 34, in an IGZO TFT device the metal layer 33 may include tungsten, hafnium, titanium, or titanium nitride, or the like, or combinations thereof).

Absorption layer 34 may draw a metal out of the material of the TFT channel 32 and bind with the metal by forming an alloy or compound with the metal. In some embodiments, a material of the absorption layer 34 may be a conductive material selected to alloy or compound with a material of the TFT channel. For instance, in a TFT device in which the TFT channel 32 includes indium (e.g., is doped with indium), and the absorption layer 34 may include lead, arsenic, or some other material that alloys or compounds readily with dopant. The absorption layer 34 may draw out the indium and form an alloy (e.g., indium lead) or a compound (e.g., indium arsenic). Such an alloy or compound may have a higher melting point than a melting point of indium. This may relax thermal processing requirements (e.g., permit a subsequent process with a higher temperature, say, one between the melting point of the pure metal and the melting point of the alloy or compound) to be applied to a TFT device employing the plural layer contact structure without causing melted indium to race through the TFT device (e.g., without causing damage to the film of the TFT device).

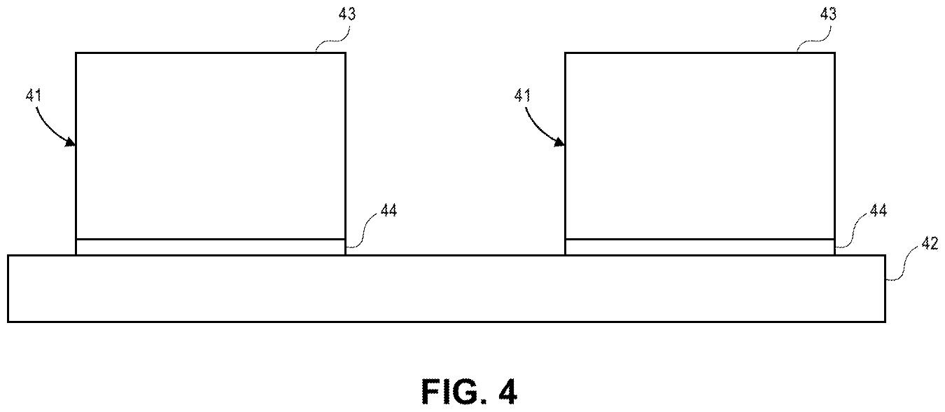

FIG. 4 is an illustration of an example contact plural layer structure including contacts 41 that each include a barrier layer 44, according to various embodiments. Due to the barrier layer 44, the metal layer 43 of the pair of contacts 41 need not be limited to the example non-reactive metals described with reference to FIGS. 2A-C (for instance, due to the barrier layer 44, in an IGZO TFT device the metal layer 43 may include tungsten, hafnium, titanium, or titanium nitride, or the like, or combinations thereof).

In contrast to absorption layer 34 (FIG. 3), barrier layer 44 may be an insulator. In some embodiments, barrier layer 44 may include a tunneling oxide. A tunneling oxide material may not draw metal out of the TFT channel 42. The tunneling oxide may be selected based on band alignment with the material of the metal layer 43.

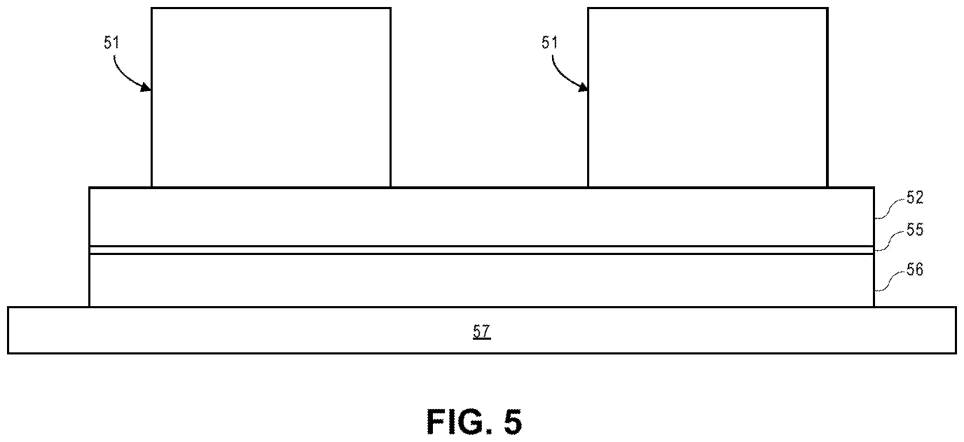

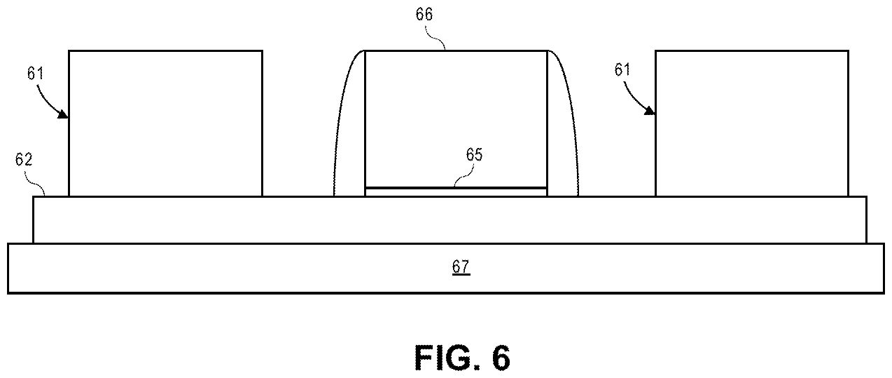

The example contact structures described herein can be used in TFT devices having any gate architecture. FIG. 5 illustrates a back-gated architecture employing contacts 51 similar to the contacts 11 (FIG. 1) or any other contacts described herein. The TFT channel 52 may be formed on an insulation layer 55 formed on a gate 56 formed on a substrate 57. FIG. 6 illustrates a non-back-gated architecture employing contacts 61 similar to the contacts 11 (FIG. 1) or any other contacts described herein. An insulation layer 65 and a gate 66 (e.g., a top gate) may be formed on a TFT channel 62 formed on a substrate 67.

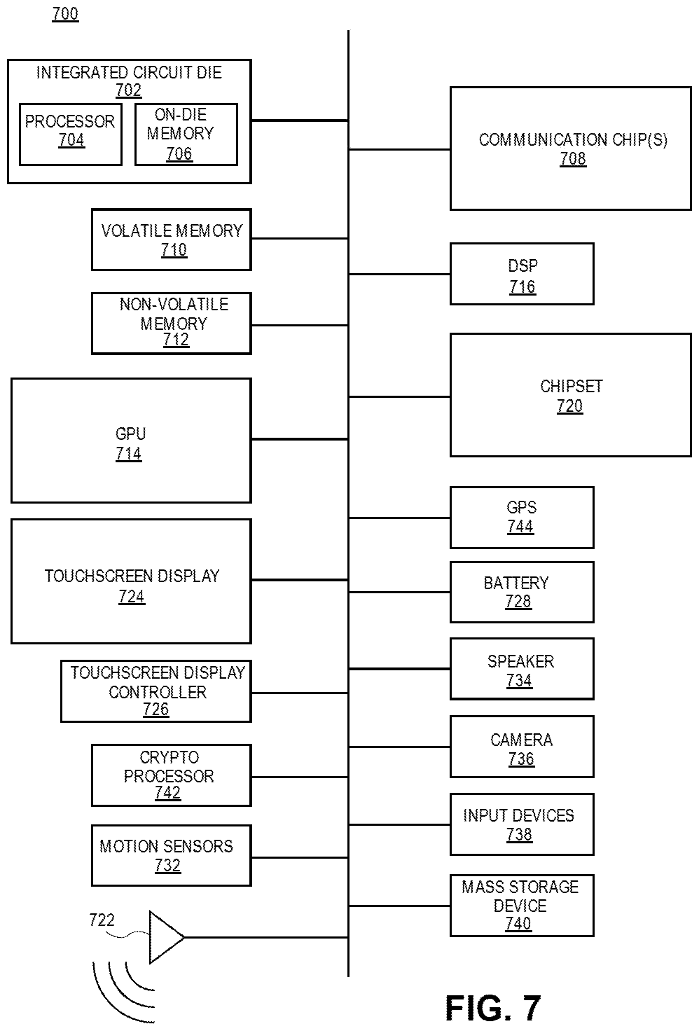

FIG. 7 illustrates a computing device 700 in accordance with various embodiments of the present disclosure. The computing device 700 may include a number of components. In one embodiment, these components are attached to one or more motherboards. Some or all of these components may include TFT devices using any contact structure described herein. The components in the computing device 700 include, but are not limited to, an integrated circuit die 702 and at least one communications logic unit 708. In some implementations the communications logic unit 708 is fabricated within the integrated circuit die 702 while in other implementations the communications logic unit 708 is fabricated in a separate integrated circuit chip that may be bonded to a substrate or motherboard that is shared with or electronically coupled to the integrated circuit die 702. The integrated circuit die 702 may include a CPU 704 as well as on-die memory 706, often used as cache memory, that can be provided by technologies such as embedded DRAM (eDRAM), SRAM, or spin-transfer torque memory (STT-MRAM).

Computing device 700 may include other components that may or may not be physically and electrically coupled to the substrate. These other components include, but are not limited to, volatile memory 710 (e.g., DRAM), non-volatile memory 712 (e.g., ROM or flash memory), a graphics processing unit 714 (GPU), a digital signal processor 716, a crypto processor 742 (e.g., a specialized processor that executes cryptographic algorithms within hardware), a chipset 720, at least one antenna 722 (in some implementations two or more antenna may be used), a display or a touchscreen display 724, a touchscreen controller 726, a battery 728 or other power source, a power amplifier (not shown), a voltage regulator (not shown), a global positioning system (GPS) device 728, a compass 730, a motion coprocessor or sensors 732 (that may include an accelerometer, a gyroscope, and a compass), a microphone (not shown), a speaker 734, a camera 736, user input devices 738 (such as a keyboard, mouse, stylus, and touchpad), and a mass storage device 740 (such as hard disk drive, compact disk (CD), digital versatile disk (DVD), and so forth). The computing device 700 may incorporate further transmission, telecommunication, or radio functionality not already described herein. In some implementations, the computing device 700 includes a radio that is used to communicate over a distance by modulating and radiating electromagnetic waves in air or space. In further implementations, the computing device 700 includes a transmitter and a receiver (or a transceiver) that is used to communicate over a distance by modulating and radiating electromagnetic waves in air or space.

The communications logic unit 708 enables wireless communications for the transfer of data to and from the computing device 700. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communications logic unit 708 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Infrared (IR), Near Field Communication (NFC), Bluetooth, derivatives thereof, as well as any other wireless protocols that are designated as 3G, 4G, 5G, and beyond. The computing device 700 may include a plurality of communications logic units 708. For instance, a first communications logic unit 708 may be dedicated to shorter range wireless communications such as Wi-Fi, NFC, and Bluetooth and a second communications logic unit 708 may be dedicated to longer range wireless communications such as GPS, EDGE, GPRS, CDMA, WiMAX, LTE, Ev-DO, and others.

The processor 704 of the computing device 700 includes one or more devices, such as TFT devices (e.g., short channel length TFT devices) having any contact structure described herein. In some embodiments, the processor 704 may include one or more layers formed on the device layer 33 of FIG. 1. The term “processor” may refer to any device or portion of a device that processes electronic data from registers and/or memory to transform that electronic data into other electronic data that may be stored in registers and/or memory.

The communications logic unit 708 may also include one or more devices such as TFT devices (e.g., short channel length TFT devices) having any contact structure described herein. In some embodiments, the communications logic unit 708 may include one or more layers formed on the device layer 33 of FIG. 1.

In various embodiments, the computing device 700 may be a laptop computer, a netbook computer, a notebook computer, an ultrabook computer, a smartphone, a dumbphone, a tablet, a tablet/laptop hybrid, a personal digital assistant (PDA), an ultra mobile PC, a mobile phone, a desktop computer, a server, a printer, a scanner, a monitor, a set-top box, an entertainment control unit, a digital camera, a portable music player, or a digital video recorder. In further implementations, the computing device 700 may be any other electronic device that processes data.

### EXAMPLES

Example 1 is a thin film transistor (TFT) device, comprising: a substrate; a gate formed above the substrate; a TFT channel formed above the substrate; and a pair of contacts formed on the TFT channel, wherein each of the contacts comprises one or more layers including: a metal that is non-reactive with a material of the TFT channel; or a plurality of layers including a first metal layer formed on a second layer, the second layer in contact with the TFT channel and between the first mater layer and the TFT channel.

Example 2 may include the subject matter of example 1 and/or any other example herein, wherein the second layer of the plurality of layers comprises a metal-absorption layer to draw a metal from the material of the TFT channel.

Example 3 may include the subject matter of any of examples 1-2 and/or any other example herein, the metal-absorption layer to alloy with the metal from the material of the TFT channel.

Example 4 may include the subject matter of any of examples 1-3 and/or any other example herein, wherein a melting point of the alloy is greater than a melting point of the metal.

Example 5 may include the subject matter of any of examples 1-4 and/or any other example herein, the metal-absorption layer to form a compound with the metal from the TFT channel.

Example 6 may include the subject matter of any of examples 1-5 and/or any other example herein, wherein the second layer of the plurality of layers comprises an insulating barrier.

Example 7 may include the subject matter of any of examples 1-6 and/or any other example herein, wherein the insulating barrier comprises a tunneling oxide.

Example 8 may include the subject matter of any of examples 1-7 and/or any other example herein, wherein a Gibs free energy value (J/mol) of the metal of the one or more layers is less negative than a Gibs free energy value (J/mol) of the TFT channel.

Example 9 may include the subject matter of any of examples 1-8 and/or any other example herein, wherein the gate comprises a back-gate, and wherein the TFT channel is formed on the back-gate.

Example 10 may include the subject matter of any of examples 1-9 and/or any other example herein, wherein the gate comprises a top-gate.

Example 11 is a thin film transistor (TFT) device, comprising: a substrate; a gate formed above the substrate; a TFT channel formed above the substrate; and a pair of contacts formed on the TFT channel, wherein each of the contacts comprises one or more layers including: a metal that is non-reactive with a material of the TFT channel, wherein a Gibs free energy value (J/mol) of the metal of the one or more layers is less negative than a Gibs free energy value (J/mol) of the TFT channel; or a plurality of layers including a first metal layer formed on a second layer, the second layer in contact with the TFT channel and between the first mater layer and the TFT channel, wherein the second layer comprises an absorption layer or an insulating barrier.

Example 12 may include the subject matter of example 11 or any other example herein, wherein the insulating barrier comprises a tunneling oxide.

Example 13 may include the subject matter of any of examples 11-12 or any other example herein, the metal-absorption layer to alloy or compound with the metal from the material of the TFT channel.

Example 14 may include the subject matter of any of examples 11-13 or any other example herein, wherein the gate comprises a back-gate, and wherein the TFT channel is formed on the back-gate.

Example 15 may include the subject matter of any of examples 11-14 or any other example herein, wherein the gate comprises a top-gate.

Example 16 is a system, comprising: a processor; a memory coupled to the processor; wherein the memory or the processor includes a thin film transistor (TFT) device, wherein the TFT device comprises: a substrate; a gate formed above the substrate; a TFT channel formed above the substrate; and a pair of contacts formed on the TFT channel, wherein each of the contacts comprises one or more layers including: a metal that is non-reactive with a material of the TFT channel; or a plurality of layers including a first metal layer formed on a second layer, the second layer in contact with the TFT channel and between the first mater layer and the TFT channel.

Example 17 may include the subject matter of example 16 or any other example herein, wherein the memory comprises a high performance CMOS (complementary metal-oxide-semiconductor), a back end memory, eDRAM (embedded dynamic random access memory), or eSRAM (embedded static random access memory).

Example 18 may include the subject matter of any of examples 16-17 or any other example herein, wherein the second layer of the plurality of layers comprises a metal-absorption layer to draw a metal from the material of the TFT channel.

Example 19 may include the subject matter of any of examples 16-18 or any other example herein, wherein the second layer of the plurality of layers comprises an insulating barrier.

Example 20 may include the subject matter of any of examples 16-19 or any other example herein, wherein a Gibs free energy value (J/mol) of the metal of the one or more layers is less negative than a Gibs free energy value (J/mol) of the TFT channel.

The above description of illustrated implementations of various embodiments, including what is described in the Abstract, is not intended to be exhaustive or to limit the present disclosure to the precise forms disclosed. While specific implementations of, and examples for, various embodiments are described herein for illustrative purposes, various equivalent modifications are possible within the scope of the present disclosure, as those skilled in the relevant art will recognize.

What is claimed is:

1. A thin film transistor (TFT) device, comprising:
a substrate;
a gate formed above the substrate;
a TFT channel formed above the substrate; and
a pair of contacts formed on the TFT channel, wherein each of the contacts comprises one or more layers including:
a metal that is non-reactive with a material of the TFT channel; or
a plurality of layers including a first metal layer formed on a second layer, the second layer in contact with the TFT channel and between the first mater layer and the TFT channel.

2. The TFT device of claim 1, wherein the second layer of the plurality of layers comprises a metal-absorption layer to draw a metal from the material of the TFT channel.

3. The TFT device of claim 2, the metal-absorption layer to alloy with the metal from the material of the TFT channel.

4. The TFT device of claim 3, wherein a melting point of the alloy is greater than a melting point of the metal.

5. The TFT device of claim 2, the metal-absorption layer to form a compound with the metal from the TFT channel.

6. The TFT device of claim 1, wherein the second layer of the plurality of layers comprises an insulating barrier.

7. The TFT device of claim 6, wherein the insulating barrier comprises a tunneling oxide.

8. The TFT device of claim 1, wherein a Gibs free energy value (J/mol) of the metal of the one or more layers is less negative than a Gibs free energy value (J/mol) of the TFT channel.

9. The TFT device of claim 1, wherein the gate comprises a back-gate, and wherein the TFT channel is formed on the back-gate.

10. The TFT device of claim 1, wherein the gate comprises a top-gate.

11. A thin film transistor (TFT) device, comprising:
a substrate;
a gate formed above the substrate;
a TFT channel formed above the substrate; and
a pair of contacts formed on the TFT channel, wherein each of the contacts comprises one or more layers including:
a metal that is non-reactive with a material of the TFT channel, wherein a Gibs free energy value (J/mol) of the metal of the one or more layers is less negative than a Gibs free energy value (J/mol) of the TFT channel; or
a plurality of layers including a first metal layer formed on a second layer, the second layer in contact with the TFT channel and between the first mater layer and the TFT channel, wherein the second layer comprises an absorption layer or an insulating barrier.

12. The TFT device of claim 11, wherein the insulating barrier comprises a tunneling oxide.

13. The TFT device of claim 11, the metal-absorption layer to alloy or compound with the metal from the material of the TFT channel.

14. The TFT device of claim 11, wherein the gate comprises a back-gate, and wherein the TFT channel is formed on the back-gate.

15. The TFT device of claim 11, wherein the gate comprises a top-gate.

16. A system, comprising:
a processor;
a memory coupled to the processor;
wherein the memory or the processor includes a thin film transistor (TFT) device, wherein the TFT device comprises:
a substrate;
a gate formed above the substrate;
a TFT channel formed above the substrate; and
a pair of contacts formed on the TFT channel, wherein each of the contacts comprises one or more layers including:
a metal that is non-reactive with a material of the TFT channel; or
a plurality of layers including a first metal layer formed on a second layer, the second layer in contact with the TFT channel and between the first mater layer and the TFT channel.

17. The system of claim 16, wherein the memory comprises a high performance CMOS (complementary metal-oxide-semiconductor), a back end memory, eDRAM (embedded dynamic random access memory), or eSRAM (embedded static random access memory).

18. The system of claim 16, wherein the second layer of the plurality of layers comprises a metal-absorption layer to draw a metal from the material of the TFT channel.

19. The system of claim 16, wherein the second layer of the plurality of layers comprises an insulating barrier.

20. The system of claim 16, wherein a Gibs free energy value (J/mol) of the metal of the one or more layers is less negative than a Gibs free energy value (J/mol) of the TFT channel.
